(19) United States
(12) Patent Application Publication
(10) Pub. No.: US 2009/0148782 A1
(43) Pub. Date: Jun. 11, 2009

(54) EXPOSURE METHOD, PHOTO MASK, AND RETICLE STAGE

(76) Inventors: Takuya Kono, Kanagawa (JP); Tetsuro Nakasugi, Kanagawa (JP); Masamitsu Ito, Kanagawa (JP); Tatsuhiko Higashiki, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/330,653

(22) Filed: Dec. 9, 2008

(30) Foreign Application Priority Data
Dec. 10, 2007 (JP) 2007-318574

(51) Int. Cl. G03F 1/00; G03F 7/20

(52) U.S. Cl. 430/5; 430/322

(57) ABSTRACT

An exposure method includes setting a photo mask into an exposure apparatus. The exposure apparatus includes an opening/closing unit configured to block a part of exposure light from a light source to the wafer. The photo mask having a product area in which a pattern to be used when a central part of a wafer is exposed is formed and peripheral exposure areas in each of which a pattern to be used when a peripheral area is exposed is formed. The peripheral exposure areas are formed to have a plurality of types of pattern densities. Then, a peripheral part of the wafer exposed. When exposing, the opening/closing unit is opened such that one or more of exposed photo mask areas selected from among the peripheral exposure areas has a pattern density corresponding to a shot position of the peripheral part.

### CROSS-REFERENCE TO RELATED APPLICATIONS

This application is based upon and claims the benefit of priority from the prior Japanese Patent Application No. 2007-318574, filed on Dec. 10, 2007; the entire contents of which are incorporated herein by reference.

### BACKGROUND OF THE INVENTION

1. Field of the Invention

The present invention relates to an exposure method, a photo mask, and a reticle stage.

2. Description of the Related Art

Scanning exposure (scanning projection exposure) is one of the exposure methods used in semiconductor lithography. In this scanning exposure, by repeating scanning projection of an image of a mask pattern that is on a photo mask onto a part of wafer for one shot (scanning projection of a mask pattern), and step movement to an adjacent shot, exposure of multiple shots are performed on the surface of the wafer, thereby projecting the image of the mask pattern on the substantially entire surface of the wafer.

When performing scanning exposure on one piece of wafer, particularly at the perimeter of the wafer, it may happen that a part of the image of a mask pattern for one shot lies off the wafer, i.e. outside of the wafer. If such a situation occurs, only a part of the mask pattern is actually transferred onto the wafer. Conventionally, the same exposure processing was performed irrespective of whether the position of the shot is in the central area of the wafer or at the perimeter of the wafer. A related art has been disclosed, for example, in JP-A H7-161614 (KOKAI) (pages 7 and 8, and FIG. 5).

Various pattern densities (amount of patterns formed per unit area) are distributed in one mask pattern because of the fact that one mask pattern includes various patterns such as memories and logics. Therefore, if the mask pattern that can be transferred onto the wafer is only a certain area (a part) thereof, like a shot in the exposure area at the perimeter, the pattern density of this area is to differ from that of one shot. As a result, in the above conventional technique, the pattern density of a pattern transferred onto an exposure area at the perimeter differs from the pattern density of a pattern transferred in a central area of a wafer. The pattern transferred in a shot in the exposure area at the perimeter cannot form a product chip corresponding one chip, in some cases. Even such a pattern affects the pattern size of a product chip therearound that is adjacent on a center side of the wafer at the time of etching. Accordingly, there has been a problem that the pattern size after etching varies on the surface of the wafer.

### SUMMARY OF THE INVENTION

According to an aspect of the present invention, there is provided an exposure method of exposing a wafer by using an exposure apparatus. The exposure method includes providing the exposure apparatus that includes setting a photo mask into the exposure apparatus that includes an opening/closing unit configured to block a part of exposure light from a light source to the wafer, the photo mask having a product area in which a pattern to be used when a central part of a wafer is exposed is formed and peripheral exposure areas in each of which a pattern to be used when a peripheral area is exposed is formed, wherein the peripheral exposure areas are formed to have a plurality of types of pattern densities; and exposing a peripheral part of the wafer, the opening/closing unit being opened such that one or more of exposed photo mask areas selected from among the peripheral exposure areas has a pattern density corresponding to a shot position of the peripheral part.

According to another aspect of the present invention, there is provided an exposure method of exposing a wafer by using an exposure apparatus. The exposure method includes setting a photo mask into the exposure apparatus, the exposure apparatus including a reticle stage for mounting the photo mask and an opening/closing unit configured to block a part of exposure light from a light source to the wafer by closing a predetermined area of the photo mask or the reticle stage, the photo mask having a product area in which a pattern to be used when a central part of a wafer is exposed is formed, and the reticle stage having peripheral exposure areas in each of which a pattern to be used when a peripheral area is exposed is formed, wherein the peripheral exposure areas are formed to have a plurality of types of pattern densities; and exposing a peripheral part of the wafer, the opening/closing unit being opened such that one or more of exposed reticle stage areas selected from among the peripheral exposure areas has a pattern density corresponding to a shot position of the peripheral part.

According to still another aspect of the present invention, there is provided a photo mask including a product area in which a pattern to be used when a central part of a wafer is exposed is formed; and peripheral exposure areas in each of which a pattern to be used when a peripheral area is exposed is formed, wherein the peripheral exposure areas are formed to have a plurality of kinds of pattern densities.

### BRIEF DESCRIPTION OF THE DRAWINGS

FIG. 1 is a perspective view of a schematic configuration of an exposure apparatus according to a first embodiment of the present invention;

FIG. 2 is a schematic diagram for explaining an arrangement of exposure areas in a photo mask;

FIG. 3 is a block diagram of a configuration of the exposure apparatus according to the first embodiment;

FIG. 4 is a flowchart of an operation procedure performed by the exposure apparatus shown in FIG. 3:

FIG. 5A is a schematic diagram for explaining a blind area at the time of exposing a product area;

FIG. 5B is a schematic diagram for explaining an example of a blind area at the time of exposing one peripheral exposure area;

FIG. 5C is a schematic diagram for explaining an example of a blind area at the time of exposing a plurality of peripheral exposure areas;

FIG. 6 is a schematic diagram of an example of an exposure area on a photo mask that is set in each shot area by the exposure apparatus according to the first embodiment;

FIG. 7 is a schematic diagram of another arrangement example of exposure areas in a photo mask;

FIG. 8 is a schematic diagram for explaining an arrangement example of blinds when five blinds are provided;

FIG. 9A is a schematic diagram for explaining a blind area when a product area and a peripheral exposure area are processed at the same time;

FIG. 9B is another schematic diagram for explaining the blind area when the product area and the peripheral exposure area are processed at the same time;

FIG. 10 is a schematic diagram of an example of an exposure area on a photo mask that is set in each shot area by an exposure apparatus according to a second embodiment of the present invention;

FIG. 11 is a schematic diagram of a configuration of a reticle stage of an exposure apparatus according to a third embodiment of the present invention;

FIG. 12A is a schematic diagram for explaining an example of a blind area at the time of exposing a pattern formed on a photo mask; and

FIG. 12B is a schematic diagram for explaining an example of a blind area at the time of exposing a pattern formed in a reticle stage.

### DETAILED DESCRIPTION OF THE PREFERRED EMBODIMENTS

Exemplary embodiments of an exposure method, a photo mask, and a reticle stage according to the present invention will be explained below in detail with reference to the accompanying drawings. The present invention is not limited to these embodiments.

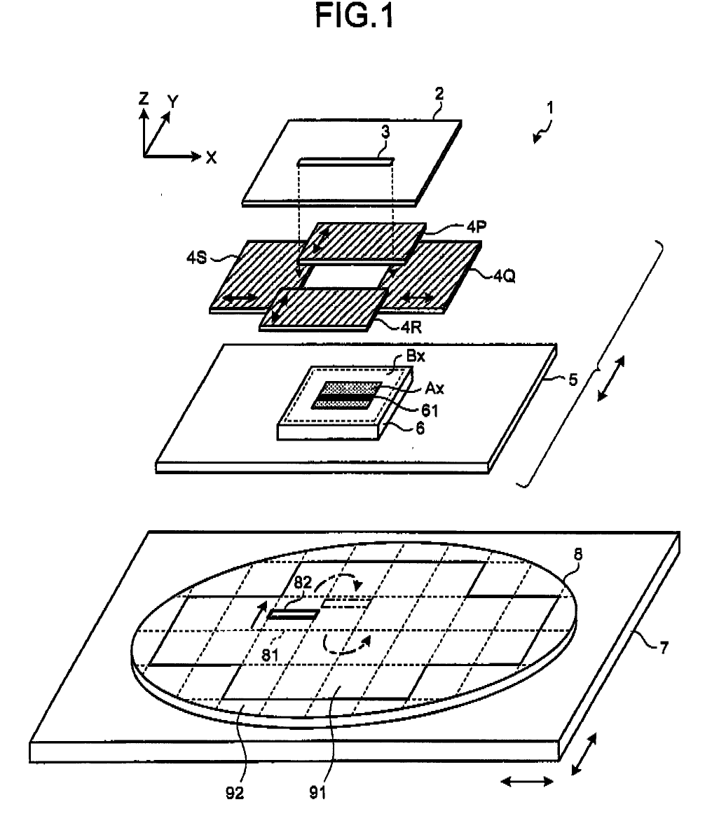

FIG. 1 is a perspective view of a schematic configuration of an exposure apparatus 1 according to a first embodiment of the present invention. For convenience of explanation, it is assumed that the horizontal plane (i.e., the plane parallel to the top surface of a wafer 8 described later) is XY-plane, and an irradiation direction of exposure light (direction perpendicular to the top surface of the wafer 8) is Z direction.

The exposure apparatus 1 performs step and scanning exposure on the wafer 8. Particularly, the exposure apparatus 1 switches, in a photo mask (reticle) 6, an area of a pattern (mask pattern) on the photo mask 6 to be transferred onto the wafer 8 depending on a part to be exposed. That is, the exposure apparatus 1 switches, in the photo mask (reticle) 6, an area of a pattern (mask pattern) on the photo mask 6 to be transferred onto the wafer 8 depending on whether the part to be exposed is a central part 91 of the wafer or a peripheral part (edge part) 92. In the first embodiment, an exposure area (a peripheral exposure area Bx described later) that is used when scanning exposure is performed on the peripheral part 92 of the wafer 8 and an exposure area (a product area Ax described later) that is used when scanning exposure is performed on the central part 91 of the wafer 8 are separately provided in the photo mask 6. Further, to avoid variation of the size after etching in the surface of the wafer 8, the pattern density (coverage) of the peripheral exposure area Bx is set to a pattern density corresponding to the pattern density of the product area Ax.

The exposure apparatus 1 includes a slit plate 2 and blinds (opening/closing unit) 4P, 4Q, 4R, and 4S that pass a part of exposure light (laser beam, X-ray, etc.) from a light source (not shown) toward a photo mask 6, a reticle stage 5 on which the photo mask 6 is mounted, and a wafer stage 7 on which the wafer 8 is mounted.

The slit plate 2 is in the shape of a substantially flat plate and it is parallel to the XY plane. The slit plate 2 passes a part of exposure light that is irradiated from the light source in the Z direction through an opening 3 toward the photo mask 6 (toward the wafer 8). The opening 3 is in a rectangular shape in which, for example, the direction of the length is the X direction, and the direction of the width is the Y direction, and passes the exposure light from the light source toward the blinds 4P to 4S while narrowing to an exposure area in a rectangular shape.

The blinds 4P to 4S respectively have a substantially rectangular plate shape parallel to the XY plane, and are configured to be movable freely in the XY plane. The exposure light from the opening 3 passes through only an area surrounded by the blinds 4P to 4S. Thus, the blinds 4P to 4S pass the exposure light from the opening 3 only to a predetermined exposure area (the product area Ax or the like) in the photo mask 6.

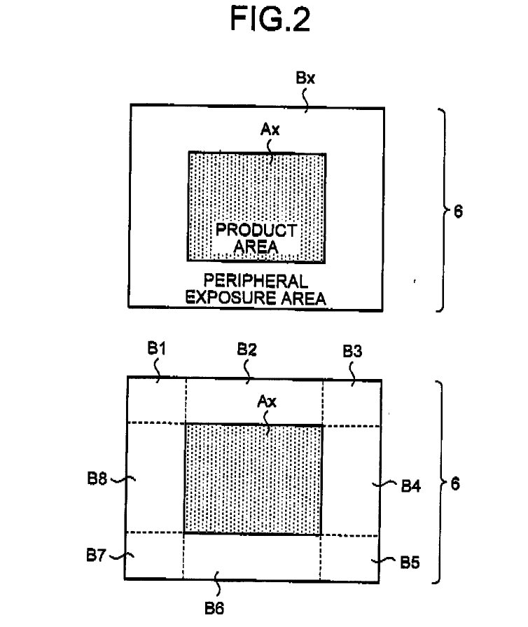

The product area Ax and the peripheral exposure area Bx, which are the exposure areas in the photo mask 6, will now be explained in detail below. FIG. 2 is a schematic diagram for explaining the arrangement of the exposure areas in the photo mask. In FIG. 2, the arrangement of the product area Ax and the peripheral exposure area Bx when viewed from the Z direction (top) are shown. Hereinafter, in the explanation of each component of the exposure apparatus 1 viewed from the Z direction, right, left, up, and down directions in the explanation indicate right, left, up, and down directions when each component is viewed from the Z direction. As shown in FIG. 2, in the photo mask 6, the product area Ax is arranged in the center of the photo mask 6 as a pattern to be transferred onto the wafer 8 (on a resist film), and the peripheral exposure area Bx surrounds the product area Ax.

The product area Ax is an exposure area (main area) corresponding to one shot in which product chips are aligned, and is used when the entire area of the product area Ax can fit in the wafer 8. In other words, the product area Ax is used for exposure of the central part 91 and the like in which a pattern in the product area Ax does not lie off the wafer 8.

A predetermined area (a part of the peripheral exposure area Bx) in the peripheral exposure area Bx is an exposure area corresponding to one shot. The peripheral exposure area Bx is a dummy exposure area to expose a peripheral shot (near the periphery) of the wafer 8, and is used for a shot position (peripheral part 92) adjacent to the product area Ax. The peripheral exposure area Bx is used for exposure of a peripheral shot in which only a part of the product area Ax can be transferred onto the wafer 8. The peripheral exposure area Bx is arranged in an area from which the product area Ax is excluded from the photo mask 6 (remaining area). In the first embodiment, the pattern of the peripheral exposure area Bx is designed by a computer-aided design (CAD) device or the like so that the pattern density of the pattern to be transferred onto the wafer 8 is uniform. In other words, in the first embodiment, the pattern of the peripheral exposure area Bx is controlled such that the size (for example, depth) of the patterns formed by the product area Ax after etching is uniform between the central part (inside) of the wafer 8 and the peripheral part (outside) of the wafer 8.

In Technique 1, the pattern of the peripheral exposure area Bx is prepared so that the pattern density of an area obtained by putting the product area Ax and the peripheral exposure area Bx together is equal to the pattern density of only the product area Ax when the product area Ax and the peripheral exposure area Bx are exposed in an adjacent manner so that the product area Ax and the peripheral exposure area Bx are next to each other, for example.

In Technique 2, alternatively, the pattern of the peripheral exposure area Bx can be designed so that the pattern density of an area obtained by putting an edge area (a part of the product area Ax) that is positioned near the area on which the peripheral exposure area Bx is transferred out of the area on which the product area Ax is transferred and the peripheral exposure area Bx together is equal to the pattern density of only the product area Ax.

Because various patterns such as memory and logic are formed in the product area Ax, various pattern densities are distributed in the product area Ax. For example, in the product area Ax, the pattern density in an upper left part and the pattern density in a bottom right part can differ from each other. Therefore, in the first embodiment, pattern having various pattern densities are arranged even in the peripheral exposure area Bx.

As shown in FIG. 2, for example, an upper left part of the peripheral exposure area Bx that is adjacent to an upper left part (upper left point) of the product area Ax is referred to as B1, an upper part of the peripheral exposure area Bx that is adjacent to an upper part (upper side) of the product area Ax is referred to as B2, and an upper right part of the peripheral exposure area Bx that is adjacent to an upper right part (upper right point) of the product area Ax is referred to as B3. Furthermore, a right part of the peripheral exposure area Bx that is adjacent to a right part (right side) of the product area Ax is referred to as B4, a bottom right part of the peripheral exposure area Bx that is adjacent to a bottom right part (bottom right point) of the product area Ax is referred to as B5, and a bottom part of the peripheral exposure area Bx that is adjacent to a bottom part (bottom side) of the product area Ax is referred to as B6. Moreover, a bottom left part of the peripheral exposure area Bx that is adjacent to a bottom left part (bottom left point) of the product area Ax is referred to as B7, and a left part of the peripheral exposure area Ex that is adjacent to a left part (left side) of the product area Ax is referred to as B8. Each of the peripheral exposure areas B1 to B8 is narrower than the product area Ax.

In the first embodiment, the patterns of the peripheral exposure areas B1 to B8 are designed so that the pattern density of an area obtained by putting a peripheral part of the product area Ax and either of the peripheral exposure areas B1 to B8 together is equal to the pattern density of only the product area Ax (Technique 2). An other words, each of the patterns of the peripheral exposure areas B1 to B8 are designed by taking into account the pattern density of a portion of the product area Ax that is near the peripheral exposure areas B1 to B8.

Specifically, the pattern of the peripheral exposure area B1 is designed so that the pattern density of an area obtained by putting the upper left part of the product area Ax and the peripheral exposure area B1 together is equal to the pattern density of only the product area Ax. Similarly, the patterns of the peripheral exposure areas B2 to B8 are designed so that the pattern density of an area obtained by putting the upper part, the upper right part, the right part, the bottom right part, the bottom part, the bottom left part, and the left part of the product area Ax and the peripheral exposure areas B2, B3, B4, B5, B6, B7, and B8 together, respectively and the pattern density of only the product area Ax are equal.

In Technique 3, the pattern of a product chip arranged in the product area Ax is arranged in the peripheral exposure area Bx. For example, one to more than one row of product chips are arranged outside (right, left, top, and bottom) of the product area Ax, and the pattern of these product chips arranged outside are to be the pattern of the peripheral exposure area Bx. In this case, for example, an optical proximity correction (OPC) processing is performed on the peripheral exposure area Bx, to make the pattern size of the peripheral exposure area Bx equal to or larger than the pattern size of the product chip arranged at an outermost part in the product area Ax. Furthermore, the pattern size of the peripheral exposure area Bx can be determined by performing the OPC processing so that the pattern size of the pattern formed using the peripheral exposure area Bx is equal to the pattern size of the pattern formed using the product area Ax.

In the exposure apparatus 1 (a blind-area setting unit 14 described later), as a shot position at which peripheral exposure is performed using the peripheral exposure area Bx, an exposure area on the photo mask 6 corresponding to the pattern in the product area Ax near this shot position is set by selecting from among the peripheral exposure areas B1 to B8. For example, when exposure is performed with the peripheral exposure area Bx at a shot position of the upper left part of the product area Ax on the photo mask 6, the exposure is performed with the peripheral exposure area B1 whose pattern is designed corresponding to the pattern density of the upper left part of the product area Ax. Similarly, when exposure is performed with the peripheral exposure area Bx at each shot position of the upper part, the upper right part, the right part, the bottom right part, the bottom part, the bottom left part, and the left part of the product area Ax on the photo mask 6, the exposure is performed with the peripheral exposure areas B2 to B8 whose pattern is designed corresponding to the pattern density of the upper part, the upper right part, the right part, the bottom right part, the bottom part, the bottom left part, and the left part of the product area Ax, respectively.

The blinds 4P to 4S are moved to predetermined positions to pass only exposure light for the product area Ax and the peripheral exposure area Bx to be a target of exposure out of the exposure light that has passed the opening 3 toward the photo mask 6.

Specifically, the blinds 4P and 4R can freely move in the Y direction, and the blinds 4Q and 4S can freely move in the X direction. The blind 4P is arranged at on a side of the upper side in the photo mask 6 in FIG. 1, and the blind 4R is arranged on a side of the bottom side of the photo mask 6 in FIG. 1. Furthermore, the blind 45 is arranged on a side of the left side of the photo mask 6, and the blind 4Q is arranged on a side of the right side of the photo mask 6. An area that is surrounded by the blinds 4P to 4S is the area through which the exposure light can pass, and this area functions as a scanning exposure area on the photo mask 6. In other words, the distance between the blinds 4P and the blind 4R is a width of the exposure area in the Y direction on the photo mask 6, and the distance between the blind 4Q and the blind 4S is a width of the exposure area in the X direction on the photo mask 6.

In the first embodiment, the blinds 4P to 4S are moved to various positions depending on a shot position (shot area 81) of the water 8, and pass exposure light in a range corresponding to each shot area 81. When the central part 91 of the wafer 8 is to be exposed, for example, the blinds 4P to 4S pass the exposure light only to the product area Ax to expose the central part 91 of the wafer 8 out of the area of the photo mask 6 while blocking the exposure light to the peripheral exposure area Bx. Further, when the peripheral part 92 of the wafer 8 is to be exposed, the blinds 4P to 4S pass the exposure light only to a part of the peripheral exposure area Bx in a ring shape to expose the peripheral part 92 of the wafer 8 out of the area on the photo mask 6 while blocking the exposure light to an area that is not used for the exposure in the peripheral exposure area Bx and the product area Ax.

While the size of the exposure light from the opening 3 to the blinds 4P to 4S in the X direction is substantially the same as the size of the photo mask 6 in the X direction, from the opening 3 to the photo mask 6, an exposure light 61 having a rectangular area that has passed through the blinds 4P to 4S is irradiated. The exposure light 61 that is irradiated to the photo mask 6 passes toward the wafer 8 through a reduced projection lens (not shown), and falls on the water 8 as an exposure light (scanning area) 82 in a rectangular shape.

When the exposure apparatus 1 performs scanning exposure on the wafer 8, the photo mask 6 and the wafer 8 are relatively scanned in the Y direction (scanning direction), and the exposure light 61 that has passed through the opening 3 sequentially falls on the areas surrounded by the blinds 4P to 4S. Thus, the respective shot areas 81 on the wafer 8 are exposed one by one using the product area Ax and the peripheral exposure area Bx on the photo mask 6. At this time, the reticle stage 5 and the blinds 4P to 4S are moved in the Y direction in a synchronized manner so that the photo mask 6 and the blinds 4P to 4S are moved in the same direction by the same distance. Thus, only the exposure area on the photo mask 6 corresponding to the area surrounded by the blinds 4P to 4S is projected on the wafer 8.

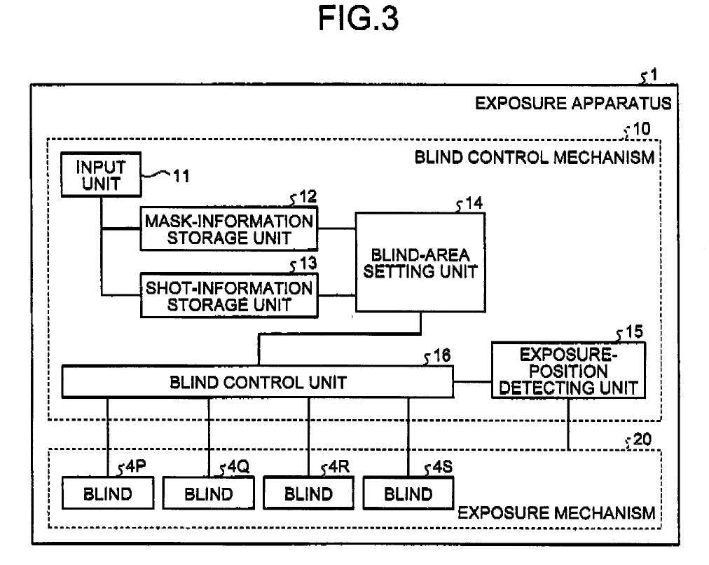

FIG. 3 is a block diagram of the exposure apparatus 1. The exposure apparatus 1 includes an exposure mechanism 20 that performs scanning exposure of the wafer 8, and a blind control mechanism 10 that controls movement of the blinds 4P and 4S.

The blind control mechanism 10 includes an input unit 11, a mask-information storage unit 12, a shot-information storage unit 13, the blind-area setting unit 14, an exposure-position detecting unit 15, and a blind control unit 16.

The input unit 11 is configured with a mouse and/or a keyboard, and is used by an operator to input mask information concerning a pattern to be formed in the photo mask 6 and shot information concerning an exposure shot position of the wafer 8.

The mask-information storage unit 12 is a storage means such as a memory that stores therein mask information input through the input unit 11. In the first embodiment, the mask-information storage unit 12 stores therein mask information concerning the product area Ax to be a shot area of a product chip in the photo mask 6 and the peripheral exposure area Bx to be a dummy shot area.

The shot-information storage unit 13 is a storage means such as a memory that stores therein shot information input through the input unit 11. The shot information includes information on a shot position to perform exposure on the wafer 8 with the product area Ax, and information on a shot position to perform exposure on the wafer 8 with the peripheral exposure area Bx.

The blind-area setting unit 14 determines an exposure area in the photo mask 6 to be used for exposure of each shot area based on the mask information in the mask-information storage unit 12 and the shot information in the shot-information storage unit 13, and sets a blind area that corresponds to the determined exposure area in the photo mask 6.

The exposure-position detecting unit 15 detects an exposure position (a shot position or a scanning position) on the wafer 8, and sends a result of the detection to the blind control unit 16. The exposure-position detecting unit 15 can detect an actual exposure position from the wafer stage 7, or can calculate an exposure position based on an exposure program indicating procedure of the exposure, an exposure condition, a time elapsed from the start of the exposure, and the like.

The blind control unit 16 calculates moving positions (amount and direction of movement) of the blinds 4P to 4S of each shot position, based on the result of detection of the exposure position sent from the exposure-position detecting unit 15 and the blind area of each shot position that is set by the blind-area setting unit 14, and controls the blinds 4P to 4S based on the result of this calculation. The blind control unit 16 moves the blinds 4P to 4S to shut areas other than the product area Ax when the exposure is performed on the wafer 8 with the product area Ax, and moves the blinds 4P to 4S to shut areas other than a part of the peripheral exposure area Bx when exposure is performed on the wafer 8 using only the part of the peripheral exposure area Bx.

The exposure mechanism 20 includes the blinds 4P to 4S and a driving device (not shown) that moves the blinds 4P to 4S. The driving device moves the blinds 4P to 4S according to the instruction from the blind control unit 16.

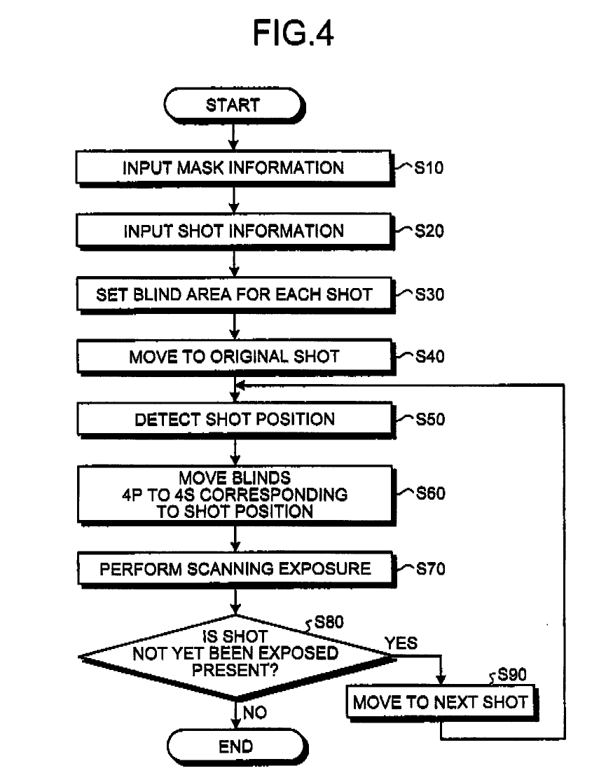

Next, the procedure of the exposure processing by the exposure apparatus 1 is explained. FIG. 4 is a flowchart of an example of an operation procedure of the exposure apparatus. The mask information and the shot information are input via the input unit 11 in advance (steps S10 and S20). The mask-information storage unit 12 stores therein the mask information and the shot-information storage unit 13 stores therein the shot information input.

The blind-area setting unit 14 determines an exposure area in the photo mask 6 to be used for exposure at each shot position based on the mask information in the mask-information storage unit 12 and the shot information in the shot-information storage unit 13, and sets a blind area corresponding to the determined exposure area on the photo mask 6 for each shot position (Step S30).

After completion of setting of the blind area by the blind-area setting unit 14, the exposure apparatus 1 moves an exposure position to an original shot position on the wafer 8 by moving the wafer stage 7, to start the exposure on the wafer 8 (Step S40).

The exposure-position detecting unit 15 detects an exposure position (shot position) on the wafer 8 (Step S50). The exposure-position detecting unit 15 sends the detected exposure position to the blind control unit 16.

The blind control unit 16 calculates movement positions of the blinds 4P to 4S based on the result of detection of the exposure position sent from the exposure-position detecting unit 15 and the blind area of each shot position that is set by the blind-area setting unit 14, and controls the blinds 4P to 4S based on the result of this calculation. Specifically, the blind control unit 16 determines which blind area is set for a shot being the exposure position, and moves each of the blinds 4P to 4S to form this blind area (Step S60).

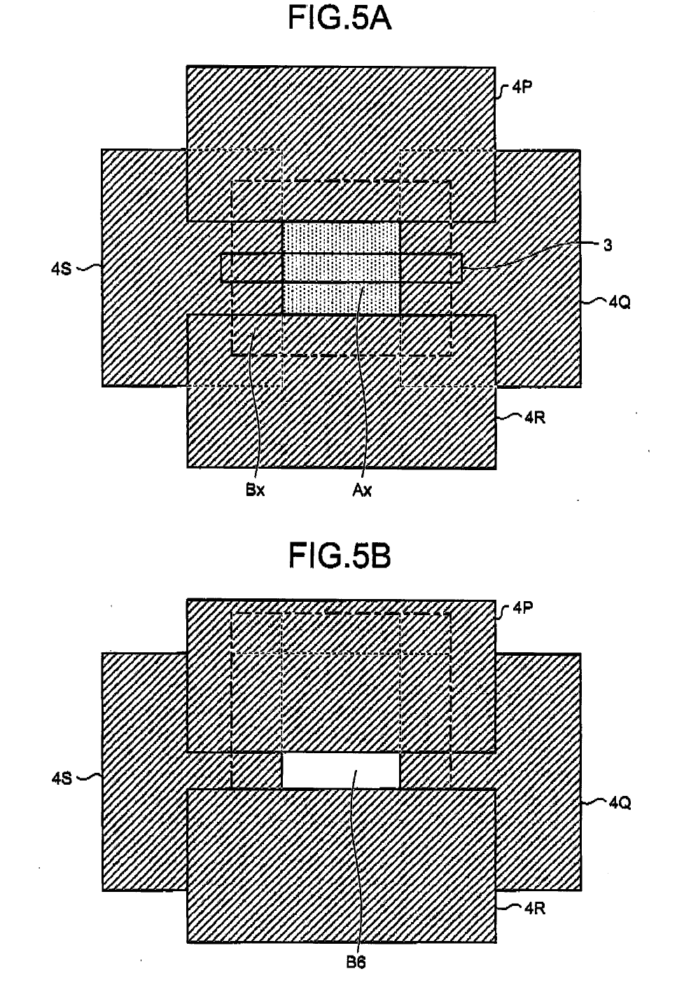

The blind area for each shot position (each exposure area) is explained herein. FIG. 5A to FIG. 5C are schematic diagrams for explaining a blind area that is set for each shot position in the exposure apparatus according to the first embodiment. In FIGS. 5A to 5C, an example of the blind area corresponding to the exposure area on the photo mask 6 set by the exposure apparatus 1 according to the first embodiment is shown.

FIG. 5A depicts a blind area (positions of the blinds 4P to 4S) at the time of exposing one shot with a product area Ax. When a shot area in the wafer 8 is to be exposed with the product area Ax, the exposure apparatus 1 entirely shuts areas (the peripheral exposure area Bx) other than the product area Ax out of the photo mask 6 with the blinds 4P to 4S.

FIG. 5B depicts a blind area at the time of exposing one shot with the peripheral exposure area B6. When a shot area in the wafer 8 is to be exposed with the peripheral exposure area B6, the exposure apparatus 1 entirely shuts areas (the product area Ax, the peripheral exposure areas B1 to B5, B7, and B8) other than the peripheral exposure area B6 out of the photo mask 6 with the blinds 4P to 4S.

When a shot area in the wafer 8 is to be exposed with either of the peripheral exposure areas B1 to B5, B7 and B8 also, similarly to the case that a shot area in the wafer 8 is exposed with the peripheral exposure area B6, the exposure apparatus 1 entirely shuts areas other than selected peripheral exposure area B1, B2, B3, B4, B5, B7, or B8 out of the photo mask 6 with the blinds 4P to 4S.

The peripheral exposure areas B1 to B8 are not limited to be exposed such that a single area is exposed as one shot, but can be exposed such that a plurality of areas (a plurality of predetermined areas selected from the peripheral exposure area Bx) are exposed as one shot, FIG. 5C depicts a blind area when one shot is exposed with the peripheral exposure areas B5 to B7. As shown in FIG. 5C, when one shot in the wafer 8 is to be exposed with the peripheral exposure areas B5 to B7, the exposure apparatus 1 entirely shuts areas (the product area Ax, the peripheral exposure areas B1 to B4, and B8) other than the peripheral exposure areas B5 to B7 out of the photo mask 6 with the blinds 4P to 4S.

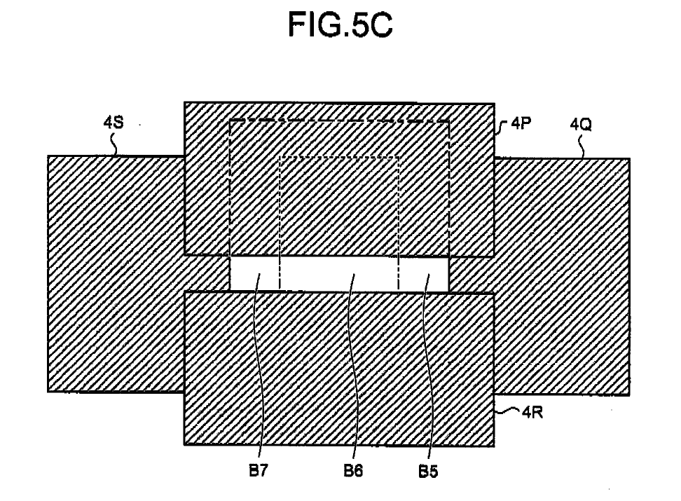

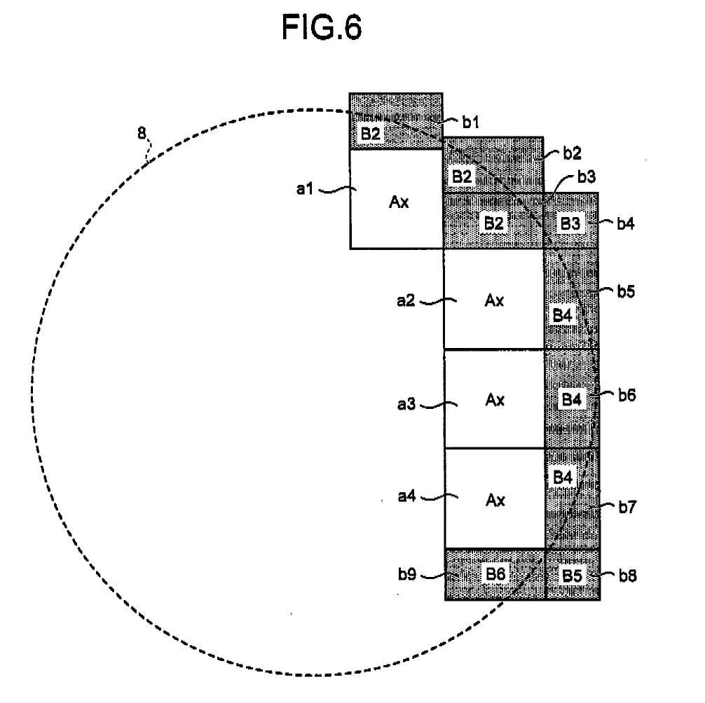

FIG. 6 is a schematic diagram of an example of an exposure area on the photo mask that is set in each shot area in the exposure apparatus 1. As shown in FIG. 6, in a shot area in which the product area Ax can be arranged on the wafer 8 without lying off to the outside of the wafer 8, the product area Ax is arranged. On the other hand, if the product area Ax lies off to the outside of the wafer 8 when the product area Ax is arranged on the wafer 8, either of the peripheral exposure areas B1 to B8 is arranged.

For example, shots (shot positions) a1 to a4 are shots in which the product area Ax can be arranged on the wafer 8 without lying off to the outside of the wafer 8. Therefore, the product area Ax is arranged in the shots a1 to a4.

If the product area Ax is arranged in the shot b1 positioned above the shot a1 in FIG. 6, the product area Ax lies off to the outside of the wafer 8. Therefore, in the shot b1, the peripheral exposure area B2 having the pattern density corresponding to the upper part of the product area Ax is arranged among the peripheral exposure areas B1 to B8.

Similarly, if the product area Ax is arranged in the shots b2 and b3 positioned above the shot a2 in FIG. 6, the product area Ax lies off to the outside of the wafer 8. Therefore, in the shots b2 and b3, the peripheral exposure area B2 having the pattern density corresponding to the upper part of the product area Ax is arranged among the peripheral exposure areas B1 to B8. The shots b2 and b3 positioned above the shot a2 are positioned also on the right of the shot a1. Therefore, the peripheral exposure area B4 corresponding to the right part of the product area Ax can be arranged in the area of the shots b2 and b3. Alternatively, the peripheral exposure areas B2 and B4 can be arranged in combination in the area of the shots b2 and b3.

Furthermore, if the product area Ax is arranged in a shot b4 positioned on the right and above the shot a2, a shot b5 positioned on the right of the shot a2, and a shot b6 positioned on the right of the shot a3, the product area Ax lies off to the outside of the wafer 8. Therefore, in the shots b4 to b6, the peripheral exposure area B3 corresponding to the upper right part of the product area Ax, the peripheral exposure area B4 corresponding to the right part of the product area Ax, and the peripheral exposure area B4 corresponding to the right part of the product area Ax are arranged, respectively.

Further, if the product area Ax is arranged in a shot b7 positioned on the right of the shot a4, a shot b8 positioned on the right and below the shot a4, and a shot b9 positioned below the shot a4, the product area Ax lies off to the outside of the wafer 8. Therefore, in the shots b7 to b9, the peripheral exposure area B4 corresponding to the right part of the product area Ax, the peripheral exposure area B5 corresponding to the bottom right part of the product area Ax, the peripheral exposure area B6 corresponding to the bottom part of the product area Ax are arranged, respectively.

The exposure apparatus 1 moves the blinds 4P to 4S to predetermined positions corresponding to a shot position, and then moves the photo mask 6, the blinds 4P to 4S, and the wafer 8 in a synchronized manner. Thereafter the exposure apparatus 1 performs scanning exposure at a current shot position (original shot herein) (Step S70).

When the scanning exposure at the current position is finished, the exposure apparatus 1 determines whether a shot area that has not been exposed is remained (Step S80). When a shot area that has not been exposed remains in the wafer 8 (YES at Step S80), the exposure apparatus 1 moves the wafer stage 7 to move the exposure position on the wafer 8 to a next shot position (Step S90).

Thereafter, the exposure-position detecting unit 15 detects an exposure position on the wafer 8 (Step S50), and the blind control unit 16 moves the blinds 4P to 4S to positions corresponding to a current shot position (Step S60). The exposure apparatus 1 then moves the photo mask 6, the blinds 4P to 4S, and the wafer 8 in a synchronized manner, and performs scanning exposure at the current shot position (Step S70).

When the scanning exposure at the current position is finished, the exposure apparatus 1 determines whether a shot area that has not been exposed remains (Step S80). When a shot area that has not been exposed remains in the wafer 8 (YES at Step S80), the exposure apparatus 1 moves the wafer stage 7 to move the exposure position on the wafer 8 to a next shot position (Step S90). Thus, the exposure apparatus 1 repeats the processes at steps S90 and S50 to S80 until no shot area that has not been exposed remains.

When no shot area that has not been exposed remains in the wafer 8 (NO at Step S80), the exposure processing on the wafer 8 is ended. Thus, the exposure apparatus 1 exposes the product area Ax or the peripheral exposure areas B1 to B8 in all the shot areas on the wafer 8.

When a next shot area after the exposure of the product area Bx is either of the peripheral exposure areas B1 to B8, the shot area of the peripheral exposure areas B1 to B8 can be exposed only by moving the blinds 4P to 4S without moving the wafer 8. For example, when the peripheral exposure area B4 is to be exposed in the shot b5 after exposing the product area Ax in the shot a2, the blinds 4P to 4S are moved such that only the product area Ax is exposed at the position of the shot a2 and exposure is performed with the product area Ax first. Subsequently, without moving the wafer 8, the blinds 4P to 4S are moved such that only the peripheral exposure area B4 is exposed and exposure is performed with the peripheral exposure area B4. As a result, the peripheral exposure area B4 is exposed at the position of the shot b5.

In the first embodiment, division of the peripheral exposure area Bx is not limited to the division into the peripheral exposure areas B1 to B8 as shown in FIG. 2B, and can be division into other areas. FIG. 7 is a schematic diagram of another arrangement example of exposure areas in the photo mask.

In the photo mask shown in FIG. 7, the peripheral exposure area B1 shown in FIG. 2 is divided into peripheral exposure areas B11 to B14. Furthermore, the peripheral exposure areas B2, B4, B6, and B8 are divided into peripheral exposure areas B15 and B16, peripheral exposure areas B17 and B18, peripheral exposure areas B19 and B20, and peripheral exposure areas B21 and B22, respectively.

In this case, the blind-area setting unit 14 sets combination of the peripheral exposure areas B1 to B8 to perform exposure, according to a shot size of a shot area at which peripheral exposure is performed. For example, when the peripheral exposure area Bx is exposed in a shot area above the product area Ax, if the shot size is equal to or larger than a predetermined size, a blind area is set so that exposure is performed with both the peripheral exposure areas B15 and B16. On the other hand, if the shot-size is smaller than the predetermined size, the blind area is set so that exposure is performed only with the peripheral exposure area B16. Accordingly, the peripheral exposure of the wafer 8 can be performed with an exposure area in a size corresponding to a shot size on the photo mask 6.

While in the first embodiment, a case that blinds prepared are the four blinds 4P to 4S has been explained, the blinds can be prepared five or more. FIG. 8 is a schematic diagram for explaining an arrangement example of blinds when five blinds are used.

In FIG. 8, an example in which a new blind 4T is added to the blinds 4P to 4S is shown. This blind 4T is formed in a substantially rectangular plate shape similarly to the blinds 4P to 4S, and is configured to be movable in the Y direction. By arranging the blind 4T next to the blind 4P (on a side of the upper side of the photo mask), area setting is enabled in the upper part of the blind area with the blind 4P and the blind 4T.

Thus, a blind area in an L-shape can be set. Furthermore, by preparing six blinds, a blind area in a T-shape or a blind area in an S-shape can be set. By further increasing the number of blinds to seven, more complex types of blind areas can be set compared to four, five, or six blinds.

It can be configured such that each of the blinds 4P to 4T is movable in both the X direction and the Y direction. With such an arrangement, various blind areas can be easily set at various positions.

While in the first embodiment, the blind-area setting unit 14 sets an exposure area in the photo mask 6 to be used for exposure of each shot area based on the mask information and the shot information, the exposure area in the photo mask 6 used for exposure of each shot area can be set manually. Particularly, the exposure area in the photo mask 6 used for exposure of each shot area is set according to an instruction externally input to the input unit 11 by a user.

Furthermore, while in the first embodiment, the peripheral exposure of the wafer 8 is performed by scanning exposure (scanning projection) using the peripheral exposure area Bx, the peripheral exposure of the wafer 8 can be performed by collective projection (stepper). In this case, both a static exposure function (static exposure means) and a scanning exposure function (dynamic exposure means) are arranged in the exposure apparatus 1. The central part 91 of the wafer 8 is exposed by scanning using the product area Ax, and the peripheral part 92 of the wafer 8 is static exposed using the peripheral exposure area Bx.

Further, it can be arranged such that the blind-area setting unit 14 extracts a necessary exposure area from the area in the peripheral exposure area Bx corresponding to the size of a shot area used for the peripheral exposure of each area and the peripheral exposure of the wafer 8 is performed using the extracted exposure area.

While in the first embodiment, a case that the peripheral exposure area Bx is formed around the product area Ax on the photo mask 6 has been explained, the peripheral exposure area Bx can be formed at any position on the photo mask 6.

While in the flowchart shown in FIG. 4, a case that the shot information is input after the mask information is input, either the mask information or the shot information can be input first. Moreover, while in the first embodiment, the blinds 4P to 4S are arranged above the photo mask 6, the blinds 4P to 4S can be arranged below the photo mask 6.

As described above, according to the first embodiment, scanning exposure is performed using the peripheral exposure area Bx that is formed according to the pattern density of the product area Ax when the peripheral exposure of the wafer 8 is performed. Therefore, the pattern density of the patterns formed on the wafer 8 can be made uniform. Accordingly, the etching speed at the time of etching the water 8 can be made uniform, and the pattern size in a product chip formed on the wafer 8 can be made uniform in the surface of the wafer 8. Thus, an effect that a wafer can be exposed in a state in which the pattern size in the surface of the wafer is stable can be obtained.

Moreover, because the peripheral exposure areas B1 to B8 are narrower than the product area Ax, when exposure is performed using the peripheral exposure areas B1 to B8, scanning area is narrower compared to when scanning exposure is performed using the product area Ax. Therefore, the time required for scanning at the time of the peripheral exposure is short, and the peripheral exposure can be performed in a shorter exposure time compared to when the peripheral exposure is performed using the product area Ax. As a result, the time of the scanning exposure (turn around time (TAT)) can be shortened, thereby improving the throughput.

Further, because the peripheral exposure areas B1 to B8 corresponding to the product area Ax are manufactured for each photo mask 6, an accurate pattern size corresponding to each photo mask 6 can be formed for various kinds of photo masks 6.

Moreover, because the pattern of each of the peripheral exposure areas B1 to B8 is designed corresponding to the pattern density of the product area Ax that is arranged near the peripheral exposure areas B1 to B8, when a next shot area after exposure of the product area Ax is either of the peripheral exposure areas B1 to B8, the shot area of the peripheral exposure areas B1 to B8 can be exposed only by moving the blinds 4P to 4S without moving the wafer 8. By such an arrangement, when exposure by the product area Ax and exposure by the peripheral exposure areas B1 to B8 are sequentially performed, the step movement of the wafer 8 can be omitted. Therefore, the distance of the step movement that is required when the entire surface of the wafer 8 is exposed can be shortened, and the wafer 8 can be exposed in a short time. Furthermore, when a plurality of the peripheral exposure areas are collectively exposed at the same time, because the movement of the blinds 4P to 4S can be omitted, the wafer 8 can be exposed in a short time.

When the peripheral exposure of the wafer 8 is performed by collective projection, the peripheral exposure of the wafer 8 can be performed in a short time compared to when the peripheral exposure is performed by scanning exposure. Therefore, the wafer 8 can be exposed speedily in a short time, thereby improving the throughput.

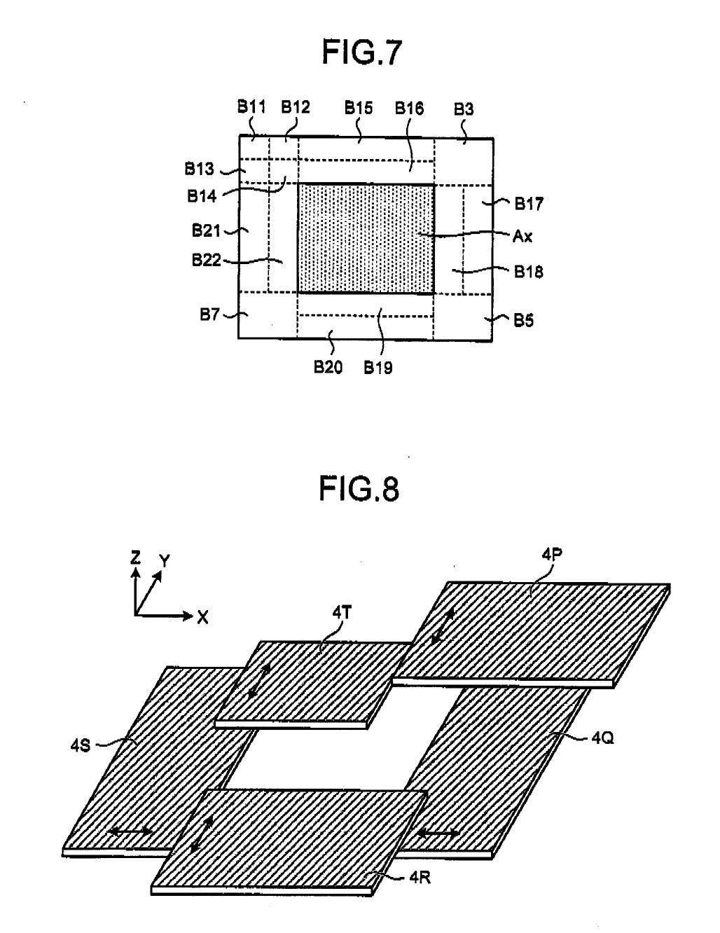

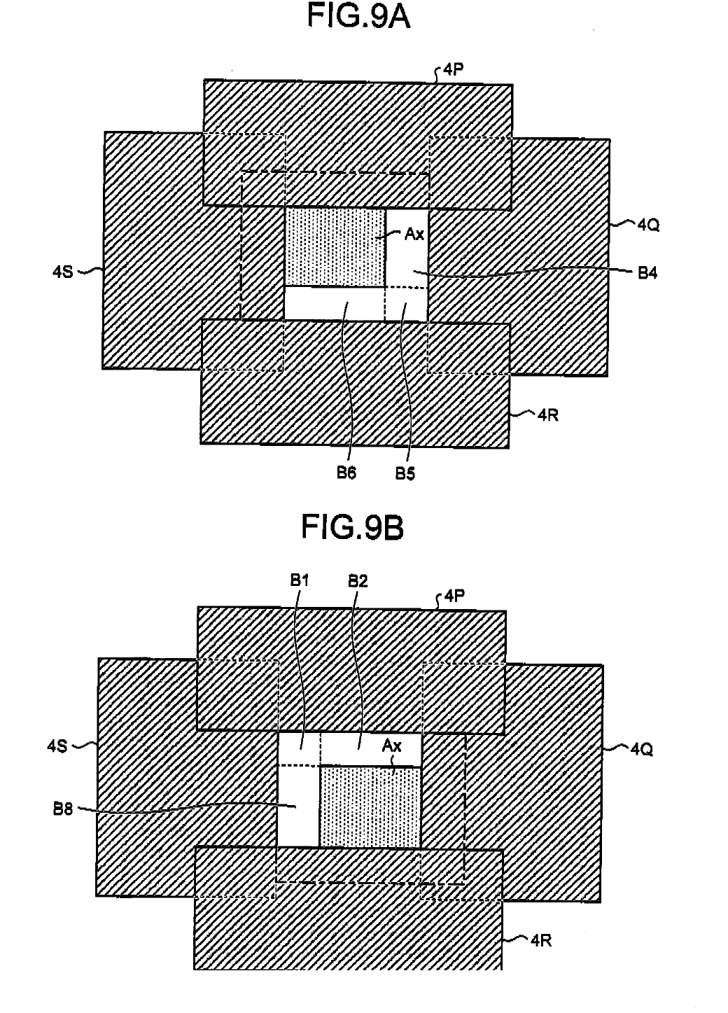

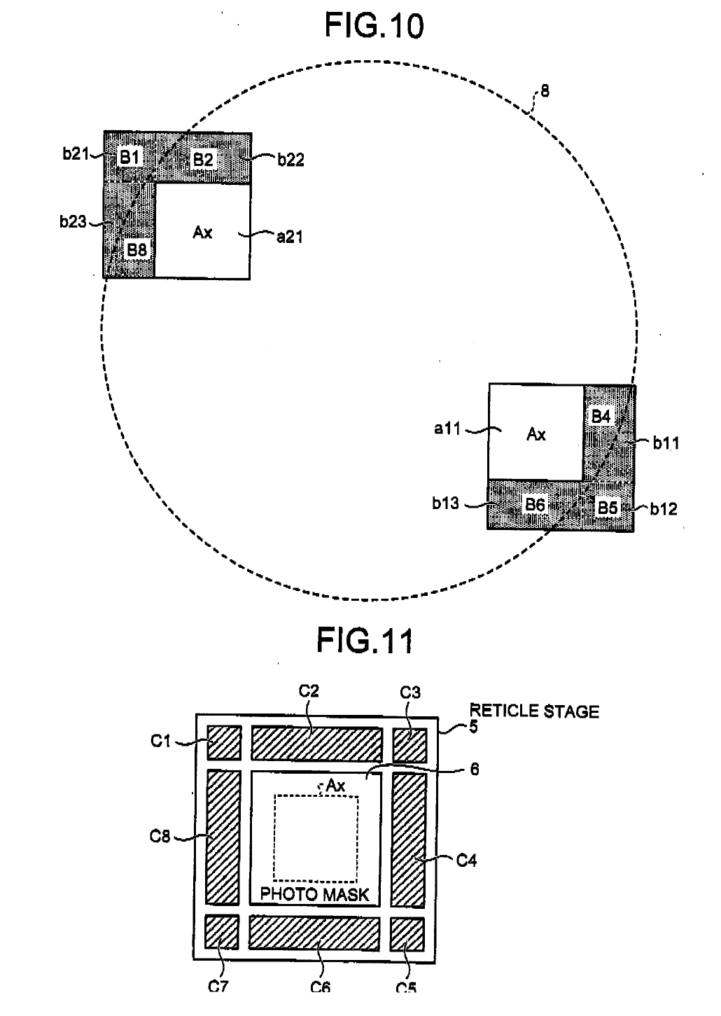

A second embodiment of the present invention is explained next with reference to FIG. 9A, FIG. 9B, and FIG. 10. In the second embodiment, when the peripheral exposure of the wafer 8 is performed, the product area Ax and a predetermined one of the peripheral exposure areas Bx are used at the same time.

FIGS. 9A and 9B are schematic diagrams for explaining a blind area when the product area and the peripheral exposure area are processed at the same time. In FIGS. 9A and 9B, an example of the blind area corresponding to an exposure area on the photo mask 6 is shown.

FIG. 9A depicts a blind area when one shot is exposed with four areas of the product area Ax and the peripheral exposure areas B4 to B6. When one shot in the wafer 8 is exposed using the product area Ax and the peripheral exposure areas B4 to B6, the exposure apparatus 1 entirely shuts areas (the peripheral exposure areas B1 to B3, B7, and B8) other than the four areas of the product area Ax and the peripheral exposure areas B4 to B6 out of the photo mask 6 with the blinds 4P to 4S.

FIG. 9B depicts a blind area when one shot is exposed with four areas of the product area Ax and the peripheral exposure areas B1, B2, and B8. When one shot in the wafer 8 is exposed using the product area Ax and the peripheral exposure areas B1, B2, and B8, the exposure apparatus 1 entirely shuts areas (the peripheral exposure areas B3 to B7) other than the four areas of the product area Ax and the peripheral exposure areas B1, B2, and B8 out of the photo mask 6 with the blinds 4P to 4S.

FIG. 10 is a schematic diagram of an example of an exposure area on a photo mask that is set in each shot area by an exposure apparatus according to the second embodiment. Also in the second embodiment, similarly to the first embodiment, in a shot area in which the product area Ax can be arranged on the wafer 8 without lying off to the outside of the wafer 8, the product area Ax is arranged. Furthermore, if the product area Ax lies off to the outside of the wafer 8 when the product area Ax is arranged on the wafer 8, either of the peripheral exposure areas Bx is arranged.

For example, shots a11 and a21 are shots in which the product area Ax can be arranged on the wafer 8 without lying off to the outside of the wafer 8. Therefore, in the shots a11 and a21, the product area Ax is arranged.

If the product area Ax is arranged in shots b11 to b13, and b21 to b23 positioned in the direction of the peripheral part of the wafer 8 relative to the shots a11 and a21, the product area Ax lies off to the outside of the wafer 8. Therefore, in the shots b11 to b13, the peripheral exposure areas B4 to B6 that correspond to the bottom right part of the product area Ax are arranged among the peripheral exposure areas B1 to B8. Moreover, in the shots b21 to b23, the peripheral exposure areas B1, B2, and B8 that correspond to the upper left part of the product area Ax are arranged among the peripheral exposure areas B1 to B8.

In the second embodiment, to expose the four areas of the product area Ax and the peripheral exposure areas B4 to B6 in one shot, a blind area shown in FIG. 9A is used as a blind area that opens the product area Ax and the peripheral exposure areas B4 to B6.

Moreover, to expose the four areas of the product area Ax and the peripheral exposure areas B1, B2, and B8 in one shot, a blind area shown in FIG. 9B is used as a blind area that opens the product area Ax and the peripheral exposure areas B1, B2, and B8.

With such an arrangement, in the peripheral part 92 of the wafer 8, either of the peripheral exposure areas B1 to B8 and the product area Ax can be exposed in one shot at the same time without moving the wafer 8 or the blinds 4P to 4S.

While in the second embodiment, a case that the product area Ax and the peripheral exposure areas B4 to B6 are exposed in one shot and a case that the product area Ax and the peripheral exposure areas B1, B2, and B8 are exposed in one shot haven been explained, combination of the peripheral exposure areas Bx to be exposed together with the product area Ax is not limited to that of the peripheral exposure areas B4 to B6 and of the peripheral exposure areas B1, B2, and B8. For example, the product area Ax and the peripheral exposure area B1 can be exposed in one shot, or the product area Ax and the peripheral exposure areas B4 to B8 can be exposed in one shot.

As described above, according to the second embodiment, either of the peripheral exposure areas B1 to B8 and the product area Ax can be exposed in one shot at the same time. Therefore, the exposure processing of the wafer 8 can be performed more speedily. Accordingly, the wafer 8 can be exposed in higher throughput than the case of the first embodiment.

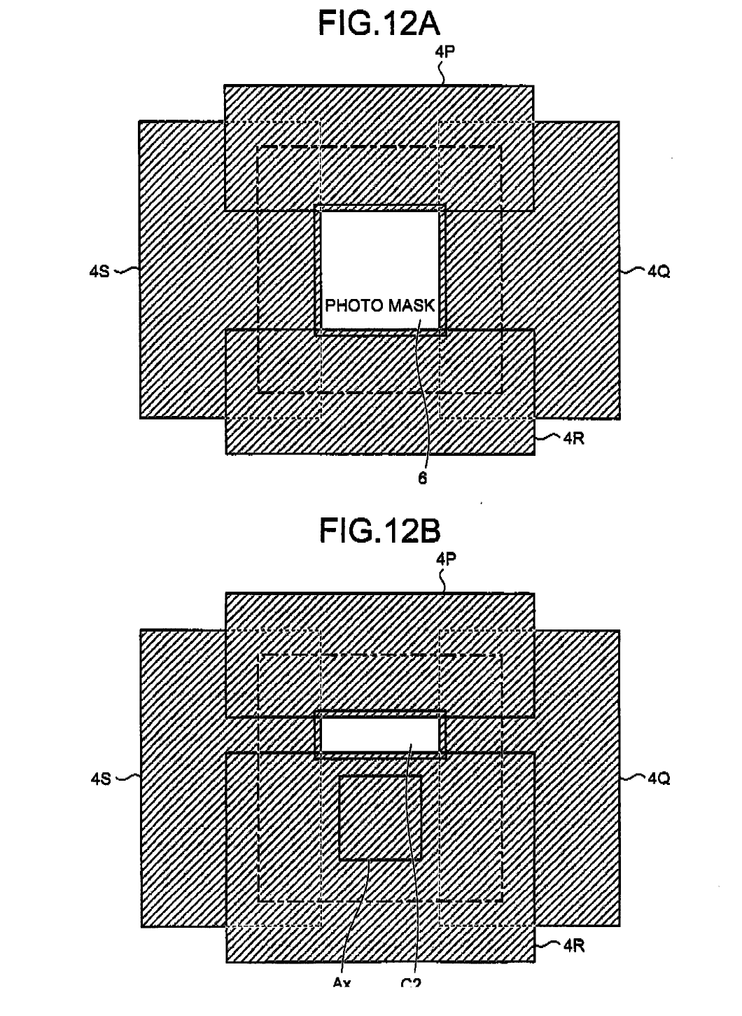

A third embodiment of the present invention is explained next with reference to FIG. 11, FIG. 12A, and FIG. 12B. In the third embodiment, patterns (peripheral exposure patterns C1 to C8 described later) to perform the peripheral exposure is provided on the reticle stage 5.

FIG. 11 is a schematic diagram of a configuration of a reticle stage of an exposure apparatus according to the third embodiment. FIG. 11 depicts an arrangement example of the peripheral exposure patterns (peripheral exposure areas) C1 to C8 on the reticle stage 5. The peripheral exposure patterns C1 to C8 are patterns used in the peripheral exposure or the like of the wafer 8, and are formed in narrower areas than the product area Ax. For example, with any pattern density of the product area Ax (when the exposure is performed using any kind of the photo mask 6), the peripheral exposure patterns C1 to C8 having various pattern densities are prepared so that the pattern density of the pattern to be transferred onto the wafer 8 is uniform in the surface of the wafer 8. The peripheral exposure patterns C1 to C8 are, for example, the same patterns as the peripheral exposure areas B1 to B8.

Next, a blind area for each shot area is explained. FIGS. 12A and 12B are schematic diagrams for explaining a blind area for each shot area set by the exposure apparatus according to the third embodiment. FIGS. 12A and 12B are an example of a blind area that corresponds to an exposure area on the photo mask 6 set by the exposure apparatus 1 according to the third embodiment.

FIG. 12A depicts a blind area at the time of exposing one shot with the product area Ax in the photo mask 6. When a shot area on the wafer 8 is exposed with the product area Ax, the exposure apparatus 1 entirely shuts areas (for example, the peripheral exposure patterns C1 to C8) other than the product area Ax out of the reticle stage 5 with the blinds 4P to 4S.

FIG. 12B depicts a blind area at the time of exposing one shot with the peripheral exposure pattern C2. When a shot area on the wafer 8 is exposed with the peripheral exposure pattern C2, the exposure apparatus 1 entirely shuts areas (the photo mask 6, the peripheral exposure patterns C1 and C3 to C8, etc.) other than the peripheral exposure pattern C2 out of the reticle stage 5 with the blinds 4P to 4S.

When a shot area in the wafer 8 is exposed with either of the peripheral exposure patterns C1, and C3 to C8 also, similarly to the case that a shot area in the wafer 8 is exposed with the peripheral exposure pattern C2, the exposure apparatus 1 entirely shuts areas other than selected peripheral exposure pattern C1, C3, C4, C5, C6, C7, or C8 out of the reticle stage 5 with the blinds 4P to 4S.

The peripheral exposure patterns C1 to C8 are not limited to be exposed such that a single area is exposed as one shot, but can be exposed such that a plurality of patterns are exposed as one shot. Alternatively, a part of the respective peripheral exposure patterns C1 to C8 can be used to perform the peripheral exposure. For example, the peripheral exposure can be performed using an upper half of the peripheral exposure pattern C2. Moreover, the same patterns as the peripheral exposure areas B1 to B8 can be arranged in the peripheral exposure patterns C1 to C8.

As described above, according to the third embodiment, the peripheral exposure is performed using the peripheral exposure patterns C1 to C8 having various pattern densities provided on the reticle stage 5. Therefore, similarly to the first embodiment, the pattern density of the patterns formed on the wafer 8 is uniform in the surface of the wafer 8. Accordingly, the pattern size in a product chip formed on the wafer 8 can be made uniform in the surface of the wafer 8.

Moreover, because the peripheral exposure patterns C1 to C8 are narrower than the product area Ax, when exposure is performed using the peripheral exposure patterns C1 to C8, scanning area is narrower compared to when scanning exposure is performed using the product area Ax. Therefore, similarly to the first embodiment, the time required for scanning at the time of the peripheral exposure is short, and the peripheral exposure can be performed in a shorter exposure time compared to when the peripheral exposure is performed using the product area Ax, thereby improving the throughput.

Furthermore, because various pattern densities are prepared in the peripheral exposure patterns C1 to C8, it is not required to manufacture the peripheral exposure areas B1 to B8 for each photo mask 6. Therefore, the exposure processing in high throughput can be performed using the photo mask 6 that has conventionally been used.

The exposure apparatus 1, the photo mask 6, and the reticle stage 5 of the first to third embodiments can be combined to perform the exposure processing of the wafer 8.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An exposure method of exposing a wafer by using an exposure apparatus, the exposure method comprising:
setting a photo mask into the exposure apparatus that includes an opening/closing unit configured to block a part of exposure light from a light source to the wafer, the photo mask having a product area in which a pattern to be used when a central part of a wafer is exposed is formed and peripheral exposure areas in each of which a pattern to be used when a peripheral area is exposed is formed, wherein the peripheral exposure areas are formed to have a plurality of types of pattern densities; and
exposing a peripheral part of the wafer, the opening/closing unit being opened such that one or more of exposed photo mask areas selected from among the peripheral exposure areas has a pattern density corresponding to a shot position of the peripheral part.

2. The exposure method according to claim 1, wherein when exposing the peripheral area, the opening/closing unit opens a predetermined photo mask area so that the predetermined photo mask area is narrower than the product area.

3. The exposure method according to claim 1, wherein the opening/closing unit opens a predetermined photo mask area selected from among the peripheral exposure areas and the product area at the same time, and the exposure light is irradiated to the wafer from the predetermined photo mask area opened by the opening/closing unit to expose the wafer.

4. The exposure method according to claim 3, wherein the opening/closing unit simultaneously opens the peripheral exposure area and the product area that are arranged adjacent to each other.

5. The exposure method according to claim 1, wherein the peripheral exposure area and the product area are exposed by scanning exposure.

6. The exposure method according to claim 1, wherein the product area is exposed by scanning exposure, and the peripheral exposure area is exposed by collective projection.

7. The exposure method according to claim 1, wherein the opening/closing unit is formed with four pieces of plate-shaped members that move independently from each other.

8. The exposure method according to claim 1, wherein the opening/closing unit is formed with five pieces of plate-shaped members that move independently from each other.

9. The exposure method according to claim 1, wherein the opening/closing unit opens the peripheral exposure area as wide as a shot area that is used when the peripheral exposure is performed.

10. An exposure method of exposing a wafer by using an exposure apparatus, the exposure method comprising:
setting a photo mask into the exposure apparatus, the exposure apparatus including a reticle stage for mounting the photo mask and an opening/closing unit configured to block a part of exposure light from a light source to the wafer by closing a predetermined area of the photo mask or the reticle stage, the photo mask having a product area in which a pattern to be used when a central part of a wafer is exposed is formed, and the reticle stage having peripheral exposure areas in each of which a pattern to be used when a peripheral area is exposed is formed, wherein the peripheral exposure areas are formed to have a plurality of types of pattern densities; and
exposing a peripheral part of the wafer, the opening/closing unit being opened such that one or more of exposed reticle stage areas selected from among the peripheral exposure areas has a pattern density corresponding to a shot position of the peripheral part.

11. The exposure method according to claim 10, wherein when exposing the peripheral area, the opening/closing unit opens a predetermined reticle stage area so that the predetermined reticle stage area is narrower than the product area.

12. The exposure method according to claim 10, wherein the opening/closing unit opens a predetermined reticle stage area selected from among the peripheral exposure areas and the product area at the same time, and the exposure light is irradiated to the wafer from the predetermined reticle stage area opened by the opening/closing unit to expose the wafer.

13. The exposure method according to claim 12, wherein the opening/closing unit simultaneously opens the peripheral exposure area and the product area that are arranged adjacent to each other.

14. The exposure method according to claim 10, wherein the peripheral exposure area and the product area are exposed by scanning exposure.

15. The exposure method according to claim 10, wherein the product area is exposed by scanning exposure, and the peripheral exposure area is exposed by collective projection.

16. The exposure method according to claim 10, wherein the opening/closing unit is formed with four pieces of plate-shaped members that move independently from each other.

17. The exposure method according to claim 10, wherein the opening/closing unit is formed with five pieces of plate-shaped members that move independently from each other.

18. The exposure method according to claim 10, wherein the opening/closing unit opens the peripheral exposure area as wide as a shot area that is used when the peripheral exposure is performed.

19. A photo mask comprising:
a product area in which a pattern to be used when a central part of a wafer is exposed is formed; and
peripheral exposure areas in each of which a pattern to be used when a peripheral area is exposed is formed,
wherein the peripheral exposure areas are formed to have a plurality of kinds of pattern densities.

20. The photo mask according to claim 19, wherein the peripheral exposure area is an area manufactured such that a pattern density of an area obtained by putting the product area and the peripheral exposure area together is equal to a pattern density of only the product area when the product area and the peripheral exposure area are exposed in an adjacent manner so that the product area and the peripheral exposure area are next to each other.
